(19) United States
(12) Patent Application Publication
(10) Pub. No.: US 2007/0063620 A1
(43) Pub. Date: Mar. 22, 2007

(54) Process monitoring device and method for process monitoring at machine tools

(75) Inventor: Werner Kluft, Aachen (DE)

Correspondence Address: Vincent L. Ramik;Suite 101, 7345 McWhorter Place, Annandale, VA, 22003, US

(73) Assignee: Werner Kluft, Annandale, VA (US)

(21) Appl. No.: 11/520,604

(22) Filed: Sep. 14, 2006

(30) Foreign Application Priority Data
Sep. 14, 2005 (EP) 05 108 449.9

(51) Int. Cl. H01L 41/00

(52) U.S. Cl. 310/338

(57) ABSTRACT

In a process monitoring device for a machine tool, especially for multiple spindle heads of a machine tool, comprising at least one working spindle driving a tool, a bearing cap biasing the bearing of the working spindle against a spindle housing of the machine tool, sensors for measuring parameters representative for the condition of the tool, and an evaluating means for evaluating the sensor measuring signals from the sensors and for outputting a control signal for an alarm means or for the machine tool, if the evaluation of the measured parameters compared to set values yield a cracking of a tool, an absent tool or an excessive tool wear, an axial surface of the bearing cap or an axial surface arranged between the bearing cap and an outer ring of the bearing of the working spindle is provided with at least one piezoelectric sensor that is non-positively connected with the axial surface and measures a force change in the axial direction of the working spindle.

### BACKGROUND OF THE INVENTION

1. Field of the Invention

The invention refers to a process monitoring device for a machine tool, especially for multiple spindle heads of a machine tool, as well as a method for process monitoring.

2. Description of Related Art

Known process monitoring devices for a machine tool, especially for a machine tool comprising multiple spindle heads, are able to monitor a plurality of working spindles simultaneously, each working spindle driving a tool. A bearing cap is used to bias the bearing of the working spindle against a spindle housing of the machine tool.

It is already known from prior art to provide distance sensors in the bearing cap that are directed against a collar or adjusting ring arranged in front of the bearing of the working spindle, the distance sensors taking a distance measure relative to this adjusting ring to measure feed forces and axial vibrations acting on the working spindle.

Here, it is disadvantageous that it is difficult to orientate the distance sensor with the adjusting ring on the spindle and that such process monitoring devices can often not be retrofitted because such an adjusting ring is not provided. Mostly, there is not enough space to retrofit such an additional ring. The distance sensors used in prior art are inductive sensors.

It is an object of the present invention to provide a process monitoring device and a method for process monitoring, especially for a machine tool comprising multiple spindle heads, with which tools can be monitored for cracking, absence or wear, and which are easy to retrofit.

### SUMMARY OF THE INVENTION

The invention advantageously provides that an axial surface of the bearing cap or an axial surface arranged between the bearing cap and an outer ring of the working spindle bearing is provided with at least one piezoelectric sensor that is non-positively connected with the axial surface and measures a force change in the axial direction of the working spindle.

Such a process monitoring device requires no additional elements and is easy to retrofit. The at least one sensor allows to measure the change in the axial force in a force bypass or a force shunt. In operation, the bearing of the working spindle is loaded axially, whereby the bias on the bearing cap or the axial surface arranged between the bearing cap and the outer ring of the working spindle bearing is relieved axially, so that the piezoelectric sensor can measure this change in force.

Preferably, the at least one sensor is provided in a recess in the axial surface of the bearing cap or of a ring arranged between the bearing cap and the working spindle. This means that the sensor generates the measuring signals only through the non-positive connection between the sensor and the axial surface and does not have to be clamped between two surfaces.

The sensor is glued non-positively to the axial surface using an adhesive.

Preferably, a plurality of mutually spaced apart sensors are provided. Here, the measuring signals of all sensors may be coupled in parallel to add the measuring signals and to obtain a measuring signal summed up circumferentially about the axis of the working spindle.

As an alternative, in particular with diametrically opposite sensors, it is possible to perform a subtraction of the measuring signals to thereby also detect radial forces occurring.

Here, the axial surface carrying the sensors is preferably facing the spindle housing of the working spindle.

### BRIEF DESCRIPTION OF THE DRAWINGS

The following is a detailed explanation of embodiments of the present invention with reference to the accompanying drawings.

In the Figures:

FIG. 1 illustrates a working spindle with a multiple spindle head;

FIG. 2 is a top plan view of a bearing cap;

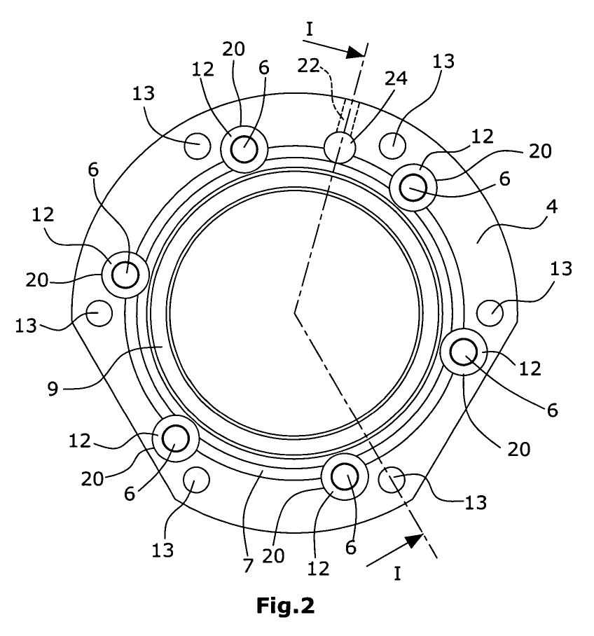

FIG. 3 is a perspective view of a bearing cap, and

FIG. 4 illustrates a bearing cap according to another embodiment of the invention.

### DETAILED DESCRIPTION OF THE PREFERRED EMBODIMENTS

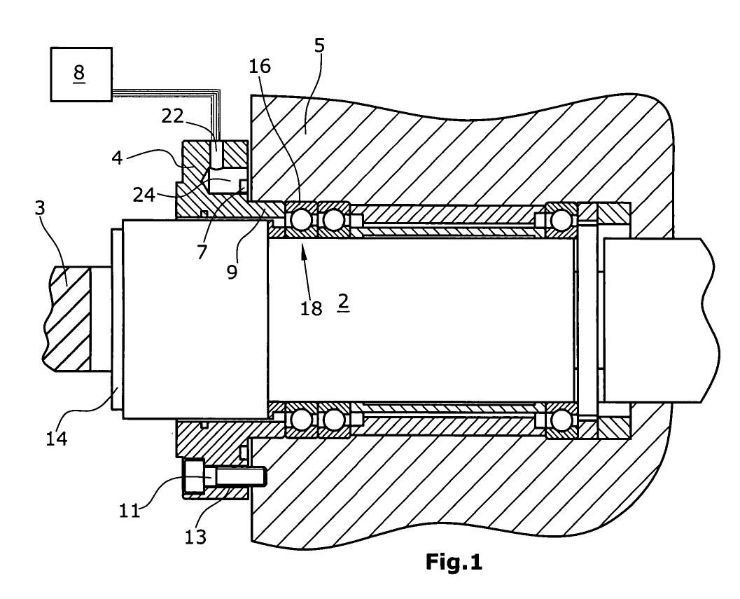

FIG. 1 illustrates a working spindle 2 of a machine tool, in particular a working spindle 2 for multiple spindle heads, wherein a plurality of working spindles are arranged closely adjacent each other. The working spindle 2 is supported in a spindle housing 5, the bearing being biased against the spindle housing 5 by means of a bearing cap 4. he bearing cap 4 has an annular collar 9 projecting towards the spindle housing 5 and abutting an outer bearing ring 16 of a first bearing 18.

In this embodiment, the bearing cap 4 is screwed in the spindle housing 5 by a total of six fastening screws 11, the bearing cap 4 having corresponding bores 13. In the vicinity of these through holes or bores 13, recesses 20 are provided whose bottoms form axial surfaces 12 for receiving sensors 6. The recesses 20 face the spindle housing 5.

Disc-shaped piezo-ceramic sensors 6 may be glued onto the bottom surfaces of the recesses 20 forming the axial surfaces 12, which sensors are thus non-positively connected with the axial surfaces 12. Depending on the force changes in the axial direction, the piezo-ceramic sensors yield a measuring signal that is supplied to an evaluating means 8. The sensors 6 are wired using an annular groove 7 connecting all recesses among each other. At one point, the annular groove 7 is connected with a channel 22, 24 leading to the outside, through which all signal lines of the sensors 6 can be guided to the outside.

The sensors 6, as well as the annular groove 7 may be covered in the recesses 20 with a pottant so that no cooling lubricant can enter the same. In this embodiment, the sensors 6 are thus only glued to the bottom surface of the recesses 20 and are not clamped between two axial surfaces. It is obvious that in another embodiment the sensors may also be embedded between two axial surfaces.

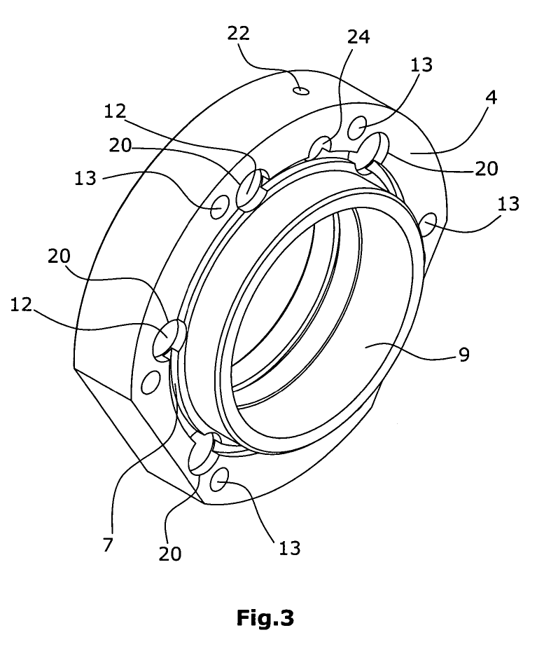

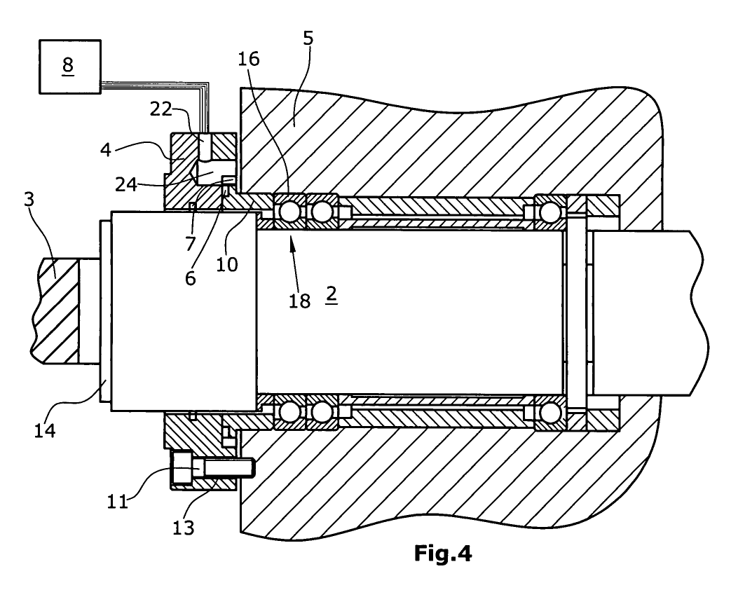

The bearing cap 4 may also be of bi-partite structure, as illustrated in FIG. 4, so that a separate ring 10 could be provided additionally in the manner of a fitting ring. In this case, the sensor 6 may preferably be sunk into an axial surface of the ring 10. As can be seen from FIG. 3, the bearing cap 4 does not have to be circular, but may be partly cut away to allow for a shorter distance between two working spindles 2.

The above described process monitoring device is advantageous in that each tool can be monitored individually for wear, cracking or the absence of a tool or work piece. The monitoring device allows to monitor any number of tools per spindle.

The sensors are arranged internally and are protected by the bearing cap 4. When retrofitting the process monitoring device, no modification of tool holders or of the working spindle 2 is required. Upon each standstill of the machine or upon a change of a work piece or when the tool is not in engagement with the work piece, the current measuring signal of the sensors 6 can be set to a zero value so that a possible temperature drift or another capacitive drift can always be compensated.

A cracking of a tool can be detected by an initially present measuring signal failing prematurely and not being present up to the cutting end of a tool. A missing tool or a missing work piece can be detected by the absence of the measuring signals of the sensors 6. An excessive tool wear can be detected through overload thresholds of the forces occurring and also by integrating the force signal over time.

As already mentioned above, the threshold values and the target values can be read in by means of a teach-in method when a fresh tool is installed.

Although the invention has been described and explained with reference to specific illustrative embodiments thereof, it is not intended that the invention be limited to those illustrative embodiments. Those skilled in the art will recognize that variations and modifications can be made without departing from the true scope of the invention as defined by the claims that follow. It is therefore intended to include within the invention all such variations and modifications as fall within the scope of the appended claims and equivalents thereof.

What is claimed is:

1. A process monitoring device for a machine tool, especially for multiple spindle heads of a machine tool, comprising at least one working spindle (2) driving a tool (3), a bearing cap (4) biasing the bearing of the working spindle (2) against a spindle housing (5) of the machine tool, sensors (6) for measuring parameters representative for the condition of the tool, and an evaluating means (8) for evaluating the sensor measuring signals from the sensors (6) and for outputting a control signal for an alarm means or for the machine tool, if the evaluation of the measured parameters compared to set values yield a cracking of a tool, an absent tool or an excessive tool wear, wherein an axial surface (12) of the bearing cap (4) or an axial surface (12) arranged between the bearing cap (4) and an outer ring (16) of the bearing of the working spindle (2) is provided with at least one piezoelectric sensor (6) that is non-positively connected with the axial surface (12) and measures a force change in the axial direction of the working spindle (2).

2. The process monitoring device of claim 1, wherein the at least one piezoelectric sensor (6) is a disc-shaped piezo-ceramic sensor.

3. The process monitoring device of claim 1, wherein the at least one sensor (6) is seated in a recess (20) in the axial surface (12) of the bearing cap (4) or a ring (10) arranged between the bearing cap (4) and the outer ring (16) of the bearing of the working spindle (2).

4. The process monitoring device of claim 1, wherein the at least one sensor (6) is non-positively connected with the axial surface (12) by means of an adhesive.

5. The process monitoring device of claim 1, wherein at least two spaced apart sensors (6) are provided.

6. The process monitoring device of claim 5, wherein the measuring signals of all sensors (6) are coupled in parallel.

7. The process monitoring device of claim 5, wherein a subtraction of the measuring signals of diametrically opposite sensors (6) is performed to measure radial forces.

8. The process monitoring device of claim 1, wherein the axial surface (12) faces the spindle housing (5) of the working spindle (2).

9. A method for process monitoring of machine tools comprising at least one working spindle (2) for driving a tool (3), the outer rings of the bearing of the working spindle (2) being adapted to be biased against a spindle housing (5) using a bearing cap (4), in particular for machine tools with multiple working spindle heads, by measuring and evaluating parameters representative for the condition of the tool, and by generating an alarm signal or a machine stop instruction if the evaluation of the measured parameters compared to set values yields a tool cracking, a absent tool or an excessive tool wear, wherein the method comprises measuring axial forces at axial surfaces (12) in the bearing cap (4) or at axial surfaces (12) between the bearing cap (4) and an outer ring (16) of the bearing of the working spindle (2) using at least one piezoelectric sensor (6) that is non-positively connected with the axial surface (12).

10. The method of claim 9, wherein a disc-shaped piezo-ceramic sensor (6) is used.

11. The method of claim 9, wherein the at least one sensor (6) is glued to the axial surface (12).

12. The method of claim 9, wherein the at least one axial surface (12) is countersunk.

13. The method of claim 9, wherein an axial surface of the bearing cap (4) facing the working spindle (2) is used.

14. The method of claim 9, wherein a plurality of preferably diametrically opposite sensors (6) is used.

15. The method of claim 9, wherein the measuring signals of all sensors (6) are coupled in parallel.

16. The method of claim 9, wherein the measuring signals of diametrically opposed sensors are subtracted from each other to measure radial forces.

17. The method of claim 9, wherein the relief, due to the axial load on the working spindle (2) upon engagement of the tool, of the axial force exerted by the bearing cap (4) on the outer rings (16) of the bearing of the working spindle (2) is measured by the sensors (6) in a force bypass.

18. The method of claim 9, wherein upon each standstill of the machine or every time the tool is out of engagement, the current measuring signals of the sensors (6) are set to a zero value.

19. The method of claim 9, wherein the set values of the measured parameters are read in by means of a teach-in method when a new tool (3) is applied for the first time.

20. The process monitoring device of claim 2, wherein the at least one sensor (6) is seated in a recess (20) in the axial surface (12) of the bearing cap (4) or a ring (10) arranged between the bearing cap (4) and the outer ring (16) of the bearing of the working spindle (2).

21. The method of claim 10, wherein the at least one sensor (6) is glued to the axial surface (12).
